(19) United States
(12) Patent Application Publication
(10) Pub. No.: US 2024/0184616 A1
(43) Pub. Date: Jun. 6, 2024

(54) MULTI-THREADED CYCLE-ACCURATE ARCHITECTURE SIMULATION

(71) Applicant: Xilinx, Inc., San Jose, CA (US)

(72) Inventors: Tharun Kumar Ksheerasagar, Jangaon (IN); Hemant Kashyap, Miyapur (IN); Amit Kasat, Hyderabad (IN); Meghana Tripathi, Hyderabad (IN); Shantanu Mishra, Hyderabad (IN)

(73) Assignee: Xilinx, Inc., San Jose, CA (US)

(21) Appl. No.: 18/075,731

(22) Filed: Dec. 6, 2022

(51) Int. Cl. G06F 9/48; G06F 9/455

(52) U.S. Cl. CPC G06F 9/48; G06F 9/455

(57) ABSTRACT

A thread manager creates multiple threads by to execute a simulation of subsystems of a system-on-chip on multiple processor cores in response to execution of a simulation program. The threads execute multiple cycle-accurate simulation models of the subsystems in parallel in an execution phase of each simulation cycle of a plurality of simulation cycles of the simulation. The threads update interfaces of the simulation models in an update phase of each simulation cycle of the plurality of simulation cycles.

### TECHNICAL FIELD

The disclosure generally relates to cycle-accurate simulation using simulation models of subsystems of a system-on-chip.

### BACKGROUND

Cycle-accurate behavior of a complex system-on-chip (SoC) is often modeled before a register transfer language (RTL) specification of the SoC is produced in order to estimate a projected level of performance. A cycle-accurate simulation of a system involves simulating cycles of a clock signal in the system and modeling behavior of the subsystems with each cycle of the clock signal. As used herein “SoC” also refers to other types of integrated circuit devices, including, for example, system-in-packages (SiPs).

The subsystems of an SoC can be simulating using simulation models of the subsystems as part of a simulation program that specifies specific operations of the subsystems to be simulated. For example, XILINX, Inc. makes complex SoCs having an array of data processing engines, a network-on-chip, programmable logic, on-chip memory, and various hard logic subsystems, each of which can have a corresponding simulation model. The simulation program can specify operations of the subsystems, such as a sequence of arithmetic operations to be performed in simulating a data processing engine. A designer can prepare a high-level simulation program (System C, C++, Verilog, SystemVerilog) that calls on the simulation models and is cycle-accurate.

### SUMMARY

A disclosed method includes creating two or more threads by a thread manager to execute a simulation of subsystems of a system-on-chip (SoC) in parallel on two or more processor cores in response to execution of a simulation program. The method includes executing two or more cycle-accurate simulation models of the subsystems in parallel by the two or more threads in an execution phase of each simulation cycle of a plurality of simulation cycles of the simulation. The method includes updating interfaces of the simulation models in an update phase of each simulation cycle of the plurality of simulation cycles.

A disclosed system includes a plurality of processor cores configured to execute program code and a memory arrangement coupled to the plurality of processor cores. The memory arrangement is configured with instructions of a simulation program and a thread manager. When executed by the plurality of processor cores, the instructions cause the plurality of processor cores to perform operations that include creating two or more threads by the thread manager to execute a simulation of subsystems of a system-on-chip (SoC) in parallel on two or more of the plurality of processor cores in response to execution of the simulation program. The operations include executing two or more cycle-accurate simulation models of the subsystems in parallel by the two or more threads in an execution phase of each simulation cycle of a plurality of simulation cycles of the simulation. The operations include updating interfaces of the simulation models in an update phase of each simulation cycle of the plurality of simulation cycles.

Other features will be recognized from consideration of the Detailed Description and Claims, which follow.

### BRIEF DESCRIPTION OF THE DRAWINGS

Various aspects and features of the methods and systems will become apparent upon review of the following detailed description and upon reference to the drawings in which:

FIG. 1 illustrates an architecture for a programmable integrated circuit (IC) device according to some examples;

FIG. 2 shows an exemplary computing arrangement configured to simulate an SoC according to the disclosed approaches; and

FIG. 3 shows a flowchart of an exemplary process of using multiple threads executing on multiple processor cores to simulate an SoC.

### DETAILED DESCRIPTION

In the following description, numerous specific details are set forth to describe specific examples presented herein. It should be apparent, however, to one skilled in the art, that one or more other examples and/or variations of these examples may be practiced without all the specific details given below. In other instances, well known features have not been described in detail so as not to obscure the description of the examples herein. For ease of illustration, the same reference numerals may be used in different diagrams to refer to the same elements or additional instances of the same element.

Conventional cycle-accurate simulations of SoCs involve single-thread execution of the simulation models. Each simulation cycle includes an execution phase and an update phase. In the execution phase, the simulation models are executed sequentially for one simulated clock cycle. In the update phase, the interfaces of the simulation models are updated sequentially. The simulation continues for a specified number of simulation cycles or until manually interrupted. Thus, assuming for simplicity that the execution phase and update phase of each of the models is t units of time, the time required to simulate m simulation models over n simulation cycles is m*n*t.

The disclosed approaches significantly reduce simulation time by assigning the simulation models for parallel execution by multiple threads on multiple processor cores without requiring the simulation program to manage the threads. According to the disclosed approaches, in response to a function call by a simulation program to commence a simulation, a thread manger starts multiple threads based on the number of processor cores selected or available to run the simulation. The simulation program, such as one prepared by a designer to evaluate the performance of an SoC and its constituent subsystems, instantiates cycle-accurate simulation models of subsystems of the SoC to be simulated, and the thread manager assigns the simulation models to the threads for execution. A simulation cycle is used in modeling cycle-accurate behavior of the simulation models. Each simulation cycle includes an execution phase and an update phase, which together simulate one cycle of the simulated clock signal.

In the execution phase, multiple simulation models are executed in parallel by the threads executing on the processor cores. A synchronization point is reached once the threads have completed the execution phase of all the simulation models. Then in the update phase, the parallel threads update the interfaces of the simulation models with signal values resulting from the execution phase. Once the interfaces of the all the simulation models have been updated, the thread manager can initiate the execution phase of another simulation cycle. Or if a desired number of simulation cycles have been completed, the thread manager can destroy the threads to complete the simulation.

According to the disclosed methods and systems, the thread manager handles deadlock avoidance, mutual exclusion, and race conditions without any involvement by the simulation program. That is, the simulation program can be written as though the simulation is performed by a single thread, and the thread manager handles issues that might arise from parallel execution without supporting code in the simulation program.

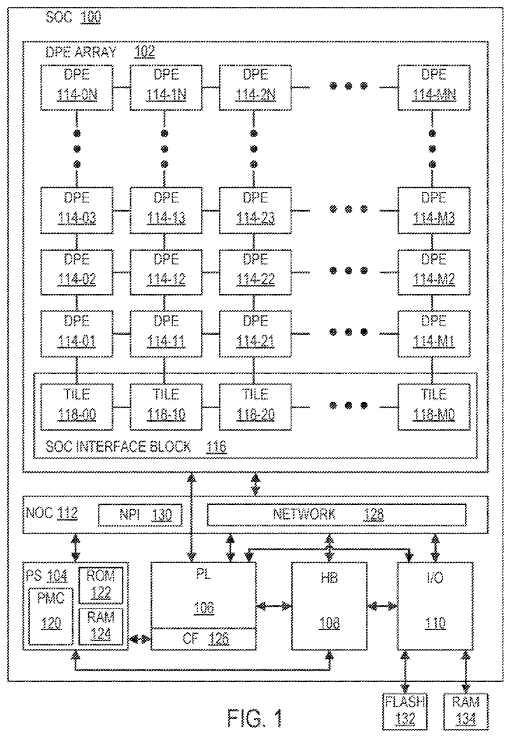

FIG. 1 illustrates an architecture for a programmable integrated circuit (IC) device according to some examples. The subsystems of the programmable IC integrated circuit have corresponding simulation models that can be executed in a simulation. In these examples, the programmable device is a System-on-Chip (SoC) 100. The architecture is generally applicable to programmable devices having higher or lower numbers of resources (e.g., DPEs) as will become apparent. The architecture can be modified with any number of variations, some of which may be identified in the following description.

The SoC 100 includes a plurality of subsystems, including a DPE array 102, a processing system (PS) 104, programmable logic (PL) 106, hard block circuits (HB) 108, input/output circuits (I/O) 110, and a Network-on-Chip (NoC) 112. In some examples, each sub-system includes at least some component or circuit that is programmable, such as described herein. In some examples, some of the sub-systems can include a non-programmable application-specific circuit. Other circuits can be included in the SoC 100, such as other IP blocks like a system monitor or others.

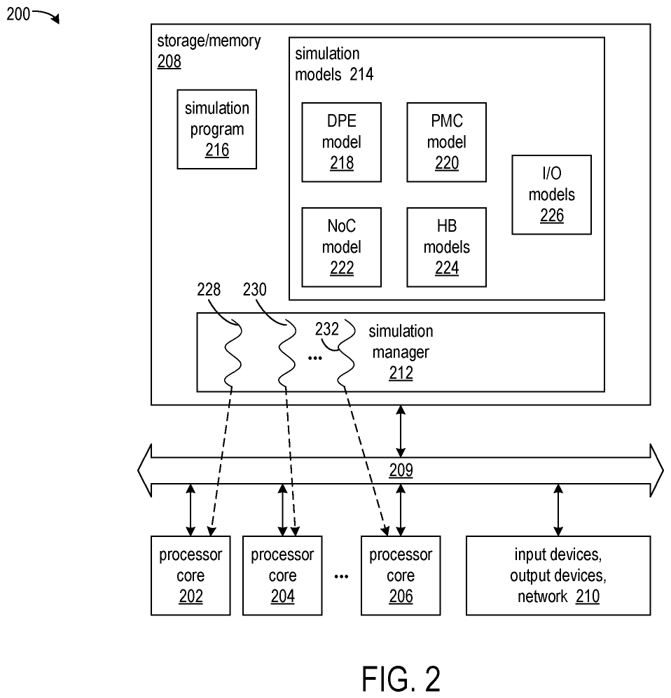

The DPE array 102 includes a plurality of interconnected DPEs 114-01 through 114-MN (collectively or individually, DPE(s) 114). Each of the DPEs 114 is a hardened circuit block and may be programmable. Each of the DPEs 114 can include the architecture as illustrated in and described below with respect to FIG. 2. In the example of FIG. 1, the DPE array 102 includes a two-dimensional array of DPEs 114 and a SoC interface block 116. The DPE array 102 may be implemented using any of a variety of different architectures. FIG. 1 illustrates DPEs 114 arranged in aligned rows and aligned columns. The DPE array 102 has M+1 columns of DPEs 114 and N rows of DPEs 114. The reference numerals of the DPEs 114 in FIG. 1 indicate the positioning of each DPE 114 by the reference number “114-[column][row].” In some examples, DPEs 114 may be arranged where DPEs 114 in selected rows and/or columns are horizontally inverted or flipped relative to DPEs 114 in adjacent rows and/or columns. In other examples, rows and/or columns of DPEs 114 may be offset relative to adjacent rows and/or columns.

As described in more detail below, the DPEs 114 can communicate various data by different mechanisms within the DPE array 102. The DPEs 114 are connected to form a DPE interconnect network. To form the DPE interconnect network, each DPE 114 is connected to vertically neighboring DPE(s) 114 and horizontally neighboring DPE(s) 114. For example, DPE 114-12 is connected to vertically neighboring DPEs 114 within column 1, which are DPEs 114-11 and 114-13, and is connected to horizontally neighboring DPEs 114 within row 2, which are DPEs 114-02 and 114-22. DPEs 114 at a boundary of the DPE array 102 may be connected to fewer DPEs 114. The DPE interconnect network includes a stream interconnect network and a memory mapped interconnect network. The stream interconnect network includes interconnected stream switches, and application data and direct memory accesses (DMAs) may be communicated between the DPEs 114 via the stream interconnect network. The memory mapped interconnect network includes interconnected memory mapped switches, and configuration data can be communicated between the DPEs 114 via the memory mapped interconnect network. Neighboring DPEs 114 can further communicate via shared memory. An independent cascade stream can be implemented between DPEs 114.

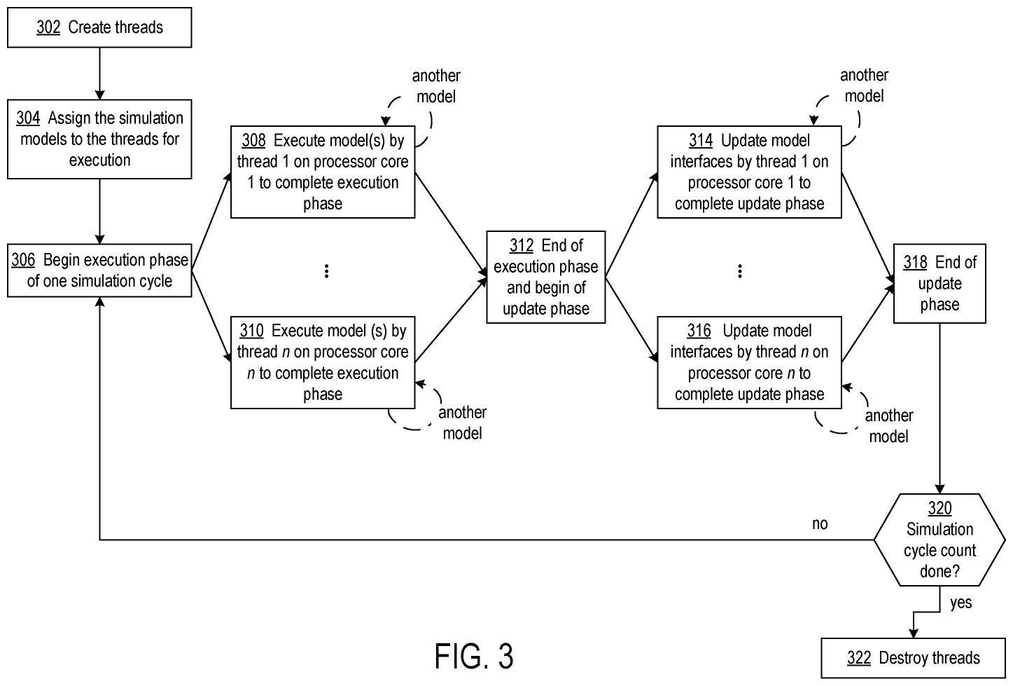

The DPE array 102 further includes the SoC interface block 116 that includes tiles 118-00 through 118-MO (collectively or individually, tile(s) 118). Each of the tiles 118 of the SoC interface block 116 may be hardened and programmable. Each of the tiles 118 can include the architecture as illustrated in and described below with respect to FIG. 3A or 3B. The SoC interface block 116 provides an interface between DPEs 114 of DPE array 102 and other subsystems of the SoC 100, such as the NoC 112 and the PL 106.

In some examples, the SoC interface block 116 is coupled to adjacent DPEs 114. For example, as illustrated in FIG. 1, the SoC interface block 116 may be connected to each DPE 114 in the bottom row of DPEs 114-x1 in the DPE array 102 (where “x” indicates a given column). More particularly, in FIG. 1, each tile 118 of the SoC interface block 116 is connected to a neighboring DPE 114 within the column of the DPE array 102 in which the respective tile 118 is disposed. In FIG. 1, tile 118-00 is connected to DPE 114-01; tile 118-10 is connected to DPE 114-11; tile 118-20 is connected to DPE 114-21; etc. Additionally, each tile 118 is connected to neighboring tiles 118. The SoC interface block 116 is capable of communicating data through the tiles 118, e.g., of propagating data from tile 118-00 to tile 118-10, from tile 118-10 to tile 118-20, etc., and vice versa. A tile 118 within the SoC interface block 116 can communicate with a DPE 114 to which the tile 118 is connected, and the communication can be routed through the DPE interconnect network formed by the interconnected DPEs 114 to a target DPE 114.

Each tile 118 can service a subset of DPEs 114 in the DPE array 102. In the example of FIG. 1, each tile 118 services the column of DPEs 114 above the respective tile 118. The tiles 118 also include stream switches, which are interconnected in the stream interconnect network to stream switches of the DPEs 114, and memory mapped switches, which are interconnected in the memory mapped interconnect network to memory mapped switches of the DPEs 114. Communications from DPEs 114 can be communicated with the tile 118 below the respective DPEs 114 via the interconnected stream switches and/or memory mapped switches. The tile 118 can provide an interface to the PL 106 and/or the NoC 112 for communications therewith.

The PS 104 may be or include any of a variety of different processor types and number of processor cores. For example, the PS 104 may be implemented as an individual processor, e.g., a single core capable of executing program instruction code. In another example, the PS 104 may be implemented as a multi-core processor. The PS 104 may be implemented using any of a variety of different types of architectures. Example architectures that may be used to implement the PS 104 may include an ARM processor architecture, an x86 processor architecture, a graphics processing unit (GPU) architecture, a mobile processor architecture, a digital signal processor (DSP) architecture, or other suitable architecture that is capable of executing computer-readable program instruction code.

The PS 104 includes a platform management controller (PMC) 120, which may be a processor and/or processor core in the PS 104 capable of executing program instruction code. The PS 104 includes read-only memory (ROM) 122 (e.g., programmable ROM (PROM) such as eFuses, or any other ROM) and random access memory (RAM) 124 (e.g., static RAM (SRAM) or any other RAM). The ROM 122 stores program instruction code that the PMC 120 is capable of executing in a boot sequence. The ROM 122 further can store data that is used to configure the tiles 118. The RAM 124 is capable of being written to (e.g., to store program instruction code) by the PMC 120 executing program instruction code from the ROM 122 during the boot sequence, and the PMC 120 is capable of executing program instruction code stored in the RAM 124 during later operations of the boot sequence.

The PL 106 is logic circuitry that may be programmed to perform specified functions. As an example, the PL 106 may be implemented as fabric of an FPGA. The PL 106 can include programmable logic elements including configurable logic blocks (CLBs), look-up tables (LUTs), random access memory blocks (BRAM), Ultra RAMs (URAMs), input/output blocks (IOBs), digital signal processing blocks (DSPs), clock managers, and/or delay lock loops (DLLs). In some architectures, the PL 106 includes columns of programmable logic elements, where each column includes a single type of programmable logic element (e.g., a column of CLBs, a column of BRAMs, etc.). The programmable logic elements can have one or more associated programmable interconnect elements. For example, in some architectures, the PL 106 includes a column of programmable interconnect elements associated with and neighboring each column of programmable logic elements. In such examples, each programmable interconnect element is connected to an associated programmable logic element in a neighboring column and is connected to neighboring programmable interconnect elements within the same column and the neighboring columns. The interconnected programmable interconnect elements can form a global interconnect network within the PL 106.

The PL 106 has an associated configuration frame interconnect (CF) 126. A configuration frame node residing on the PMC 120 is connected to the CF 126. The PMC 120 sends configuration data to the configuration frame node, and the configuration frame node formats the configuration data in frames and transmits the frames through the CF 126 to the programmable logic elements and programmable interconnect elements. The configuration data may then be loaded into internal configuration memory cells of the programmable logic elements and programmable interconnect elements that define how the programmable elements are configured and operate. Any number of different sections or regions of PL 106 may be implemented in the SoC 100.

The HB 108 can be or include memory controllers (such as double data rate (DDR) memory controllers, high bandwidth memory (HBM) memory controllers, or the like), peripheral component interconnect express (PCIe) blocks, Ethernet cores (such as a 100 Gbps (C=100) media address controller (CMAC), a multi-rate MAC (MRMAC), or the like), forward error correction (FEC) blocks, Analog-to-Digital Converters (ADC), Digital-to-Analog Converters (DAC), and/or any other hardened circuit. The I/O 110 can be implemented as extreme Performance Input/Output (XPIO), multi-gigabit transceivers (MGTs), or any other input/output blocks. Any of the HB 108 and/or I/O 110 can be programmable.

The NoC 112 includes a programmable network 128 and a NoC peripheral interconnect (NPI) 130. The programmable network 128 communicatively couples subsystems and any other circuits of the SoC 100 together. The programmable network 128 includes NoC packet switches and interconnect lines connecting the NoC packet switches. Each NoC packet switch performs switching of NoC packets in the programmable network 128. The programmable network 128 has interface circuits at the edges of the programmable network 128. The interface circuits include NoC master units (NMUs) and NoC slave units (NSUs). Each NMU is an ingress circuit that connects a master circuit to the programmable network 128, and each NSU is an egress circuit that connects the programmable network 128 to a slave endpoint circuit. NMUs are communicatively coupled to NSUs via the NoC packet switches and interconnect lines of the programmable network 128. The NoC packet switches are connected to each other and to the NMUs and NSUs through the interconnect lines to implement a plurality of physical channels in the programmable network 128. The NoC packet switches, NMUs, and NSUs include register blocks that determine the operation of the respective NoC packet switch, NMU, or NSU.

A physical channel can also have one or more virtual channels. The virtual channels can implement weights to prioritize various communications along any physical channel. The NoC packet switches also support multiple virtual channels per physical channel. The programmable network 128 includes end-to-end Quality-of-Service (QOS) features for controlling data-flows therein. In examples, the programmable network 128 first separates data-flows into designated traffic classes. Data-flows in the same traffic class can either share or have independent virtual or physical transmission paths. The QoS scheme applies multiple levels of priority across traffic classes. Within and across traffic classes, the programmable network 128 applies a weighted arbitration scheme to shape the traffic flows and provide bandwidth and latency that meets the user requirements.

The NPI 130 includes circuitry to write to register blocks that determine the functionality of the NMUs, NSUs, and NoC packet switches. The NPI 130 includes a peripheral interconnect coupled to the register blocks for programming thereof to set functionality. The register blocks in the NMUs, NSUs, and NoC packet switches of the programmable network 128 support interrupts, QoS, error handling and reporting, transaction control, power management, and address mapping control. The NPI 130 includes an NPI root node residing on the PMC 120, interconnected NPI switches connected to the NPI root node, and protocol blocks connected to the interconnected NPI switches and a corresponding register block.

To write to register blocks, a master circuit, such as the PMC 120, sends configuration data to the NPI root node, and the NPI root node packetizes the configuration data into a memory mapped write request in a format implemented by the NPI 130. The NPI transmits the memory mapped write request to interconnected NPI switches, which route the request to a protocol block connected to the register block to which the request is directed. The protocol block can then translate the memory mapped write request into a format implemented by the register block and transmit the translated request to the register block for writing the configuration data to the register block.

The NPI 130 may be used to program any programmable boundary circuit of the SoC 100. For example, the NPI 130 may be used to program any HB 108 and/or I/O 110 that is programmable.

Various subsystems and circuits of the SoC 100 are communicatively coupled by various communication mechanisms. Some subsystems or circuits can be directly connected to others. As illustrated the I/O 110 is directly connected to the HB 108 and PL 106, and the HB 108 is further directly connected to the PL 106 and the PS 104. The PL 106 is directly connected to the DPE array 102. The DPE array 102, PS 104, PL 106, HB 108, and I/O 110 are communicatively coupled together via the programmable network 128 of the NoC 112.

The programmable device illustrated in FIG. 1 can be implemented in a single monolithic integrated circuit (IC) chip, or can be implemented distributed across multiple IC chips. When implemented in multiple IC chips, the IC chips can be stacked on each other, where neighboring chips are bonded (e.g., by hybrid oxide-to-oxide and metal-to-metal bonding) to each other or are attached to each other by external connectors (e.g., minibumps or microbumps). In other examples when implemented in multiple IC chips, the chips can be attached to a common substrate, such as an interposer or a package substrate. In some examples, one chip (e.g., a base chip) can include the PS 104, HB 108, I/O 110, and NoC 112, another one or more chips (e.g., fabric chips) can include the PL 106, and a further one or more chips (e.g., DPE chips) can include the DPE array 102. In a specific example, a chips stack includes a base chip, one or more fabric chips, and a DPE chip, where neighboring chips are bonded together by hybrid bonding, and the one or more fabric chips are disposed in the chip stack between the base chip and the DPE chip.

As will become apparent, DPEs 114 and tiles 118 may be programmed by loading configuration data into configuration registers that define operations of the DPEs 114 and tiles 118, by loading configuration data (e.g., program instruction code) into program memory for execution by the DPEs 114, and/or by loading application data into memory banks of the DPEs 114. The PMC 120 can transmit configuration data and/or application data via the programmable network 128 of the NoC 112 to one or more tiles 118 in the SoC interface block 116 of the DPE array 102. At each tile 118 that receives configuration data and/or application data, the configuration data and/or application data received from the programmable network 128 is converted into a memory mapped packet that is routed via the memory mapped interconnect network to a configuration register, program memory, and/or memory bank addressed by the memory mapped packet (and hence, to a target DPE 114 or tile 118). The configuration data and/or application data is written to the configuration register, program memory, and/or memory bank by the memory mapped packet.

Using a DPE array 102 as described herein in combination with one or more other subsystems provides heterogeneous processing capabilities of the SoC 100. The SoC 100 may have increased processing capabilities while keeping area usage and power consumption low. For example, the DPE array 102 may be used to hardware accelerate particular operations and/or to perform functions offloaded from one or more of the subsystems of the SoC 100. When used with a PS 104, for example, the DPE array 102 may be used as a hardware accelerator. The PS 104 may offload operations to be performed by the DPE array 102 or a portion thereof. In other examples, the DPE array 102 may be used to perform computationally resource intensive operations.

In some examples, the SoC 100 can be communicatively coupled to other components. As illustrated, the SoC 100 is communicatively coupled to flash memory 132 and to RAM 134 (e.g., DDR dynamic RAM (DDRDRAM)). The flash memory 132 and RAM 134 may be separate chips and located, e.g., on a same board (e.g., evaluation board) as the SoC 100. The flash memory 132 and the RAM 134 are communicatively coupled to the I/O 110, which is connected to HB 108 (e.g., one or more memory controllers). The HB 108 is connected to the PS 104 (e.g., the PMC 120). The PMC 120 is capable of reading data from the flash memory 132 via the HB 108 and I/O 110, and writing the read data to local RAM 124 and/or, via the HB 108 and I/O 110, to the RAM 134.

FIG. 2 shows an exemplary computing arrangement 200 configured to simulate an SoC according to the disclosed approaches. The computing arrangement includes processor circuitry that includes multiple processor cores 202, 204, . . . , 206, coupled to storage/memory arrangement 208 through a system bus 209 or other suitable circuitry. Program code, which is executable by the processor cores and stored in the storage/memory arrangement, includes simulation models 214, simulation manager 212, and simulation program 216. The simulation program 216, with support of the simulation manager 212, directs a cycle-accurate simulation of an SoC using simulation models 214.

Each of the simulation models corresponds to a subsystem of the SoC to be simulated and when executed simulates cycle-accurate behavior of the corresponding subsystem. The simulated behavior by the simulation models is in response to configurations and/or operations specified by the simulation program 216. Examples of simulation models include DPE model 218, PMC model 220, NoC model 222, HB models 224, and I/O models 226.

The simulation program is prepared by a designer for purposes of estimating performance of the SoC and specifies configurations and/or operations of the simulation models as mentioned above. The simulation program has a single thread program view. That is, the simulation program does not specify execution of multiple threads and is “unaware” that program code (the “thread manager”) within the simulation manager handles multi-threading activity. The program code in Example 1 shows an example of a simulation program that has a single thread view of the simulation and relies on a simulation manager to handle the multi-threading activities.

```
class processor: public asc_module
//processor is a simulation model of a subsystem being modeled
//”module” used to reference a subsystem
{
  void proc_functionality( )
  {
    //specification of processor functions
  }
public:
  processor(asc_module_name name)
  {
    ASC_METHOD(proc_functionality, scheduler);
    //Method to execute in parallel with other instances
  }
  asc_out <bus_if> init_0;
  //An output port of the module, used to drive data to
  //other modules in the system
  asc_in <bool> interrupt_if;
  //An input port of the module, used to receive data from
  //other modules in the system
};
int main( )
{
  std::vector<processor> proc_array(PROCESSOR_ARRAY_SIZE,
    “processor”);
    //Creates array of processor modules
  std::vector<asc_interface<int>> interface_array;
  make_proc_inter_connections(proc_array, interface_array);
  //Connecting the modules
  /* proc_functionality method of instances in the
  * proc_array will be executed in parallel as controlled
  * by the simulation manager and without explicit
  * coordination of parallelization by the simulation model
  * /
  asc_run( );
  return 0;
}
```

### Example 1

According to one approach, the simulation program can instantiate instances of the simulation models and specify interfaces of the simulation models. The interface of a simulation model can include an input port on which input data is received from another model, and an output port at which data can be output to another model.

The simulation manager, which is also referred to as the simulation scheduler, includes program code that implements a thread manager. The thread manager creates multiple threads to execute the simulation models 214 in parallel on multiples ones of the processor cores 202, 204, . . . , 206 in response to execution of the simulation program 216. The thread manager manages the execution and update phases of simulation cycles of the threads, manages trace information, and updates global simulation time. The simulation program has a single thread program view, and the thread manager handles multi-threading activity, such as mutual exclusion, deadlock avoidance, and race conditions.

The threads are illustrated by curved lines 228, 230, . . . , 232. The simulation model(s) assigned to thread 228 are executed on processor core 202, The simulation model(s) assigned to thread 230 are executed on processor core 204, . . . , and the simulation model(s) assigned to thread 232 are executed on processor core 206.

Once the threads have completed the execution phase of a simulation cycle for all the simulation models, the threads update the interfaces of the simulation models in an update phase of the simulation cycle. The thread manager can control the threads to commence the execution phase of another simulation cycle if called for by the simulation program.

Different combinations of hardware restrictions, processing requirements of the simulation, and/or limitations imposed by the sharing of resources with other applications on the computing arrangement can influence the number of threads created by the thread manager. According to one approach, the number of threads created by the thread manager can be based on the number of processor cores available in the computing arrangement and the threads respectively assigned to execute on the processor cores. The number of “available” processor cores can be the number of processor cores present in the computing arrangement and made available by a computing system manager for the user or simulation. Alternatively, the thread manager can create a number of threads that is equal to the number of processor cores configured in the computing arrangement or specified by a user input parameter to the simulation manager (and thereby to the thread manager).

The thread manager assigns the simulation models to the threads for execution. According to one approach, the thread manager uniformly distributes the simulation models amongst the threads. For example, if there are n threads, m simulation models, and m>n, the thread manager can assign floor(m/n) simulation models to each of the threads, with each remaining simulation model assigned to a respective one of the threads. According to another approach, the simulation models can be assigned to the threads based balancing computation requirements of the models between the threads. For example, the thread manager can determine the computation and memory requirements of each of the simulation models. The thread manager can assign simulation models to the threads such that differences between the respective totals of the computation and memory requirements of simulation models assigned to the threads are minimized.

The storage/memory arrangement 208 can include one or more physical memory devices such as, a local memory (not shown) and a persistent storage device (not shown). Local memory refers to random access memory or other non-persistent memory device(s) generally used during actual execution of the program code. Persistent storage can be implemented as a hard disk drive (HDD), a solid state drive (SSD), or other persistent data storage device. The storage/memory arrangement can also include one or more cache memories that provide temporary storage of at least some program code and data in order to reduce the number of times program code and data must be retrieved from local memory and persistent storage during execution.

The computing arrangement additionally includes input/output (I/O) devices and network elements 210. The input devices can includes user input devices, such as a mouse and keyboard, and user output devices, such as a display device. The input/output devices can be coupled to the computing arrangement either directly or through intervening I/O controllers (not shown). A network adapter also can be coupled to the computing arrangement for communicative coupling to other systems and/or devices through intervening private or public networks. Modems, cable modems, Ethernet cards, and wireless transceivers are examples of different types of network adapters that can be used in combination with computing arrangement 200. The program code of simulation manager 212, simulation models 214, and simulation program 216, and any data items used, generated, and/or operated upon by the program code impart functionality when executed by the computing arrangement.

FIG. 3 shows a flowchart of an exemplary process of using multiple threads executing on multiple processor cores to simulate an SoC. At block 302, the thread manager creates multiple threads to execution simulation models on multiple processor cores of a computing arrangement. The creation of threads is in response to a simulation program commencing execution with the simulation manager. The number of threads created is generally based on the number of processor cores available in a computing arrangement as described above.

At block 304, the thread manager assigns simulation models instantiated by the simulation program to the threads. The basis on which assignments are made can be to balance the number of simulation models assigned the threads or to balance the processing and memory requirements amongst the threads.

The simulation manager begins the execution phase of a simulation cycle at block 306, with each thread executing the assigned simulation model(s) as shown by blocks 308, . . . , 310. Each thread executes the assigned simulation model(s) to completion of the execution phase, which is programmed into each simulation model. Connections between simulation models, output ports to input ports, are supported by an interface. The interface can maintain two state values: a “new value” and an “updated value” in memory. During the execution phase, a thread executing the output port of a simulation model will write to the memory address having the new value, and a thread executing the input port of a simulation model will read from the memory address having the updated value. Race conditions are avoided because the output port and input port are not accessing the same memory location. In response to a thread completing the execution phase of a simulation model, the thread manager schedules the thread to begin execution of another simulation model assigned to the thread.

Once all the threads have completed the execution phase of all the simulation models, a synchronization point is signaled to the thread manager. By forcing a synchronization point at the end of the execution phase, race conditions between the threads are avoided. At block 312 the thread manager can initiate parallel execution of the threads on the simulation models in the update phase. The threads perform processing of the update phase as specified by the simulation models as shown by blocks 314, . . . , 316. In the update phase, interfaces between simulation models are updated. An interface is generally updated by copying the new value to the memory location allocated to the updated value. Only one thread copies the new value to the updated value, thereby avoiding race conditions. The thread that performs the copying can be either the thread processing the output port or the thread processing the input port, depending on application objectives.

Once all the threads have completed the update phase of all the simulation models, a synchronization point is signaled to the simulation manager at block 318. At decision block decision block 320, the simulation manager determines whether or not a desired simulation cycle count has been reached. If not, the simulation manager initiates the execution phase of another simulation cycle at block 306. Otherwise, the thread manager destroys the threads at block 322.

Some implementations are directed to a computer program product (e.g., nonvolatile memory device), which includes a machine or computer-readable medium having stored thereon instructions which may be executed by a computer (or other electronic device) to perform these operations/activities

Though aspects and features may in some cases be described in individual figures, it will be appreciated that features from one figure can be combined with features of another figure even though the combination is not explicitly shown or explicitly described as a combination.

The methods and system are thought to be applicable to a variety of systems for simulating SoCs. Other aspects and features will be apparent to those skilled in the art from consideration of the specification. It is intended that the specification and drawings be considered as examples only, with a true scope of the invention being indicated by the following claims.

What is claimed is:

1. A method comprising:
creating two or more threads by a thread manager to execute a simulation of subsystems of a system-on-chip (SoC) in parallel on two or more processor cores in response to execution of a simulation program;
executing two or more cycle-accurate simulation models of the subsystems in parallel by the two or more threads in an execution phase of each simulation cycle of a plurality of simulation cycles of the simulation; and
updating interfaces of the simulation models in an update phase of each simulation cycle of the plurality of simulation cycles.

2. The method of claim 1, wherein updating includes updating the interfaces of the two or more simulation models in parallel by the two or more threads.

3. The method of claim 1, wherein the simulation program has a single thread program view.

4. The method of claim 3, wherein creating the two or more threads includes creating the two or more threads based on a number of available processors cores.

5. The method of claim 3, wherein creating the two or more threads includes creating each thread of the two or more threads to execute on the two or more processor cores, respectively.

6. The method of claim 3, wherein creating the two or more threads includes creating a number of threads equal to a number of processor cores configured in a computer system.

7. The method of claim 3, wherein creating the two or more threads includes creating a number of threads equal to a number of processor cores specified by a user input parameter to the thread manager.

8. The method of claim 1, wherein a number of the two or more threads is n, a number of the two or more simulation models is m, and m>n, and the method further comprising assigning at least floor(m/n) simulation models to each thread of the two or more threads for execution.

9. The method of claim 1, wherein a number of the two or more threads is n, a number of the two or more simulation models is m, and m>n, and the method further comprising:
determining computation requirements of each of the two or more simulation models; and
assigning one or more of the two or more simulation models to each of the two or more threads based on the computation requirements of the one or more simulation models assigned to the two or more threads.

10. The method of claim 1, wherein the two or more simulation models include simulation models of data processing engines of an array of data processing engines.

11. The method of claim 1, wherein the two or more simulation models include simulation models of data processing engines of an array of data processing engines and a simulation model of a network-on-chip.

12. A system comprising:
a plurality of processor cores configured to execute program code; and
a memory arrangement coupled to the plurality of processor cores, wherein the memory arrangement is configured with instructions of a simulation program and a thread manager that when executed by the plurality of processor cores cause the plurality of processor cores to perform operations including:
creating two or more threads by the thread manager to execute a simulation of subsystems of a system-on-chip (SoC) in parallel on two or more of the plurality of processor cores in response to execution of the simulation program;
executing two or more cycle-accurate simulation models of the subsystems in parallel by the two or more threads in an execution phase of each simulation cycle of a plurality of simulation cycles of the simulation; and
updating interfaces of the simulation models in an update phase of each simulation cycle of the plurality of simulation cycles.

13. The system of claim 12, wherein the instructions for updating include instructions for updating the interfaces of the two or more simulation models in parallel by the two or more threads.

14. The system of claim 12, wherein the simulation program has a single thread program view.

15. The system of claim 14, wherein the instructions for creating the two or more threads include instructions for creating the two or more threads based on a number of available processors cores.

16. The system of claim 14, wherein the instructions for creating the two or more threads include instructions for creating each thread of the two or more threads to execute on the two or more processor cores, respectively.

17. The system of claim 14, wherein the instructions for creating the two or more threads include instructions for creating a number of threads equal to a number of processor cores configured in a computer system.

18. The system of claim 14, wherein the instructions for creating the two or more threads include instructions for creating a number of threads equal to a number of processor cores specified by a user input parameter to the thread manager.

19. The system of claim 12, wherein a number of the two or more threads is n, a number of the two or more simulation models is m, and m>n, and the operations further including assigning at least floor(m/n) simulation models to each thread of the two or more threads for execution.

20. The system of claim 12, wherein a number of the two or more threads is n, a number of the two or more simulation models is m, and m>n, and the operations further including:
determining computation requirements of each of the two or more simulation models by the thread manager; and
assigning one or more of the two or more simulation models to each of the two or more threads based on the computation requirements of the one or more simulation models assigned to the two or more threads.
